(19) United States
(12) Patent Application Publication
(10) Pub. No.: US 2006/0193353 A1
(43) Pub. Date: Aug. 31, 2006

(54) High power single mode semiconductor laser device and fabrication method thereof

(75) Inventors: Bum Joon Kim, Seoul (KR); Soo Haeng Cho, Kyungki-do (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Kyungki-do (KR)

(21) Appl. No.: 11/302,817

(22) Filed: Dec. 14, 2005

(30) Foreign Application Priority Data
Feb. 28, 2005 (KR) 10-2005-0016780

(51) Int. Cl. H01S 3/098; H01S 5/00

(52) U.S. Cl. 372/19; 372/46.01; 372/50.11

(57) ABSTRACT

The present invention relates to a high-power single-mode semiconductor laser device, in which a first conductivity-type cladding layer is formed on a semiconductor substrate. An active layer is formed on the first conductivity-type cladding layer, and a second conductivity-type cladding layer is formed on the active layer, with a ridge protruding upward. The invention has corrugated parts formed on upper surfaces of the second conductivity-type cladding layer on both sides next to the ridge for scattering light in order to suppress high order mode oscillation.

### CLAIM OF PRIORITY

This application claims the benefit of Korean Patent Application No. 2005-16780 filed on Feb. 28, 2005, in the Korean Intellectual Property Office, the disclosure of which is incorporated herein by reference.

### BACKGROUND OF THE INVENTION

1. Field of the Invention

The present invention relates to a semiconductor laser device, and more particularly, to a semiconductor laser device capable of operating with stable single mode characteristics at high power.

2. Description of the Related Art

A semiconductor laser device is capable of oscillating light having narrow frequency band (short wavelength), and has high directivity, and therefore, extensively utilized as light sources for optical pick-up devices of optical disc system and applied in variety of fields including optical communication, multiplex communication, and space communication.

In general, a semiconductor laser device is manufactured as a semiconductor ridge waveguide laser (hereinafter referred to as “ridge semiconductor laser”) having a Selectively Buried Ridge (SBR) in order to enhance current injection efficiency and optical characteristics. A ridge semiconductor laser has small effective refractive index difference in horizontal direction, and thus there is a drawback of likely occurrence of high order mode at high power.

In order to achieve a single mode, the width of the semiconductor laser ridge is required to be narrow. Particularly, in order to obtain the short wavelength of light such as visible ray region or ultraviolet ray region in a single mode, the ridge is formed as narrow as 1 to 3 μm. However, such ridge with a narrow width causes increased resistance of device or operation voltage, negatively affecting the reliability of the device, with occurrence of high order mode.

In order to suppress high order mode occurring at high power, there have been techniques of additionally forming oxidation film, semiconductor layer, and metal layer to absorb light on both side regions of the ridge where high order mode exists. Alternatively, as shown in FIG. 1a, there have been techniques of forming roughened surfaces or wave patterns on both side surfaces of the ridge to induce light loss through light scattering.

FIG. 1a illustrates a semiconductor laser device 10 with a first conductivity-type cladding layer 12, an active layer 14, and a second conductivity-type cladding layer 15 formed in their order. On the top of the second conductivity-type cladding layer 15, a ridge R is formed with wave patterns P on both side surfaces thereof. A second conductivity-type cap layer 17 may be added onto the upper surface of the ridge.

The wave patterns formed on both side surfaces of the ridge R induces light loss through waveguiding scattering to suppress high order mode (FIG. 1b). However, when forming irregular side surfaces of ridge, it may be difficult to form an exact structure of desired ridge. Especially, when forming a ridge having a narrow width in order to realize short-wavelength single mode, it is difficult to design and form exact width due to the roughened surface of the ridge.

Moreover, when forming an upper electrode in the actual manufacturing, the area for formation of electrode may be irregular in shape due to the roughened surfaces of the ridge, which may possibly cause defective connection of the electrode, undermining the electrical characteristics of the semiconductor laser device. Furthermore, since much heat is generated in the contact region of the ridge contacting the upper electrode, the light scattering effect of the roughened surface may be unstable due to undesired effect from the heat.

### SUMMARY OF THE INVENTION

The present invention has been made to solve the foregoing problems of the prior art and it is therefore an object of the present invention to provide a semiconductor laser device which has corrugated parts, formed on the upper surfaces of the cladding layer on both sides next to the ridge, for scattering light to suppress the occurrence of high order light.

It is another object of the invention to provide a fabrication method of the semiconductor laser device.

According to an aspect of the invention for realizing the object, the present invention provides a semiconductor laser device including: a semiconductor substrate; a first conductivity-type cladding layer formed on the semiconductor substrate; an active layer formed on the first conductivity-type cladding layer; and a second conductivity-type cladding layer formed on the active layer, the second conductivity-type cladding layer having a ridge protruding upward, and corrugated parts formed on upper surfaces of the second conductivity-type cladding layer on both sides next to the ridge for scattering light in order to suppress high order mode oscillation.

The corrugated parts may be formed from lower edges of the ridge, but depending on the region of high order mode oscillation, the corrugated parts may be formed apart in a predetermined interval from the lower edges of the ridge.

The corrugated parts may take diverse forms, for example, wave patterns in parallel to the ridge or perpendicular to the ridge. In addition, the corrugated parts may have regular spacings and depths as well as irregular spacings and depths.

Preferably, the spacing of the corrugated parts is shorter than the wavelength of the laser and longer than ½ of the wavelength of the laser, in order to scatter light of the laser more effectively.

Moreover, the present invention provides a fabrication method of the semiconductor laser device including steps of: forming a first conductivity-type cladding layer, an active layer and a second conductivity-type cladding layer on a semiconductor substrate in their order; selectively etching the upper part of the second conductivity-type cladding layer, thereby forming a ridge protruding upward; and forming corrugated parts on upper surfaces of the second conductivity-type cladding layer on both sides next to the ridge for scattering light in order to suppress high order oscillation.

### BRIEF DESCRIPTION OF THE DRAWINGS

The above and other objects, features and other advantages of the present invention will be more clearly understood from the following detailed description taken in conjunction with the accompanying drawings, in which:

FIG. 1a is an overall perspective view of a conventional semiconductor laser device;

FIG. 1b is an overall view illustrating light scattering effect by corrugated parts of a ridge shown in FIG. 1a;

FIG. 2 is an overall perspective view illustrating a semiconductor laser device according to an embodiment of the present invention;

FIG. 3a is an overall perspective view illustrating a semiconductor laser device according to another embodiment of the present invention;

FIG. 3b is a graph illustrating fundamental mode and high order mode distributions along the width direction of the semiconductor laser device of FIG. 3a;

FIGS. 4a and 4b are overall perspective views each illustrating semiconductor laser device having modified corrugated parts according to alternate embodiments of the present invention;

FIGS. 5a and 5b are graphs illustrating the suppression effect of high order mode oscillation in an AlGaInP-based semiconductor laser device.

### DETAILED DESCRIPTION OF THE PREFERRED EMBODIMENT

Preferred embodiments of the present invention will now be described in detail with reference to the accompanying drawings.

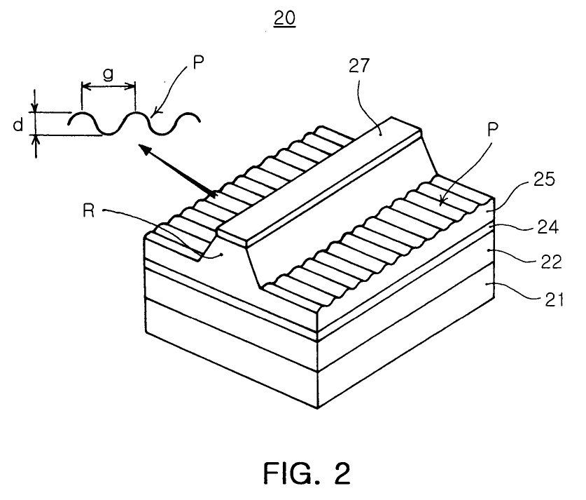

FIG. 2 is an overall perspective view illustrating a semiconductor laser device 20 according to an embodiment of the present invention. As shown in FIG. 2, the semiconductor laser device 20 includes a semiconductor substrate 21, and a first conductivity-type cladding layer 22, an active layer 24, and a second conductivity-type cladding layer 25 formed on the semiconductor substrate 21 in their order.

The upper area of the second conductivity-type cladding layer 25 is selectively etched to form a ridge R. On the top of the ridge R, a second cap layer 27 may additionally be formed.

The upper area of the second conductivity-type cladding layer 25 on both sides next to the ridge R may have wave patterns P formed for scattering light in specific regions. As in the embodiment of the present invention, the wave patterns P may have waves parallel to the ridge (or oscillation direction of the fundamental mode).

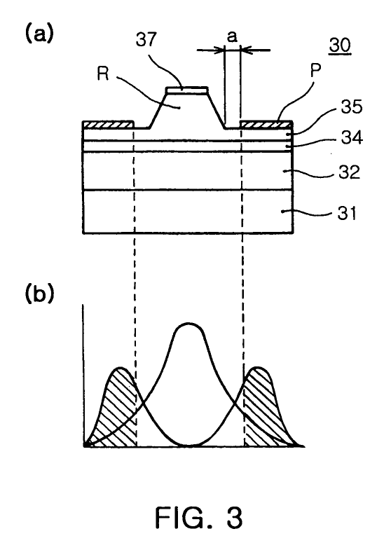

In the embodiment of the present invention, the corrugated parts are illustrated as formed from the lower edge of the ridge R, but they may be formed in appropriate positions in the main oscillation region of high order mode according to the design of the laser herein. The “main oscillation region of high order mode” refers to the upper area of the second conductivity-type cladding layer 25 along the width direction of the semiconductor laser, and the invention is aimed to sufficiently suppress the oscillation of high order mode in the main oscillation region of high order mode, as will be illustrated in detail with reference to FIG. 3b.

The wave patterns P formed on the upper area of the second conductivity-type cladding layer 25 on both sides next to the ridge R induce light loss to suppress high order mode, through waveguiding scattering in specific region, i.e., light scattering in the main oscillation region of high order mode. The wave patterns P are not formed directly on both side surfaces of the ridge R, facilitating the design/formation of desired structure of ridge, thereby preventing weakening of electrical characteristics due to defective connection with upper electrode. In addition, as the wave patterns are formed apart from the formation area of the electrode where intensive heat is generated, unstable effect of light scattering due to such heat can be minimized.

The spacing g and depth d of the wave patterns P may be appropriately selected depending on the wavelength. The spacing g and depth d may be in a regular form but also may be in irregular forms. Preferably, the spacing g of the waves is shorter than the wavelength of the laser light and longer than ½ of the wavelength of the laser light.

FIG. 3a is an overall perspective view illustrating a semiconductor laser device according to another embodiment of the present invention. The semiconductor laser device 30, similar to FIG. 2, includes a semiconductor substrate 31, and a first conductivity-type cladding layer 32, an active layer 34, and a second conductivity-type cladding layer 35 formed on the semiconductor substrate in their order. The upper part of the second conductivity-type cladding layer 35 has a ridge R. On the upper surface of the ridge, a second conductivity-type cap layer 37 may be formed additionally.

The wave patterns P formed on the upper surface of the second conductivity-type cladding layer 35 may be in similar shape with FIG. 2, but are formed apart from the ridge in a predetermined interval a, in the main oscillation region of high order mode.

The wave patterns are formed in the main oscillation region of high order mode so that a maximum area of high order mode distribution overlaps with fundamental mode distribution while the loss of fundamental mode is kept to a minimum. As shown in FIG. 3b, the fundamental mode distribution is in a symmetrical form with one peak in the center of the ridge while the high order mode (second order mode) distribution has peaks on both sides next to the peak of the fundamental mode distribution, overlapping with the tails of the fundamental mode distribution. Therefore, it is preferable that the wave patterns P for suppressing high order mode are formed at the areas where the high order mode distribution steeply increases in order to suppress high order mode oscillation. It is more preferable that the wave patterns P are formed apart in a predetermined interval a from the ridge where the loss of the fundamental mode is at a minimum.

More specifically, it is preferable that the wave patterns P start forming at the point where the high order mode distribution is at about 80% (integral area) or higher, and more preferably, the point at 80% or higher of high order mode distribution and 20% or lower of the fundamental mode distribution. However, the formation area of the wave patterns P according to the fundamental mode and high order mode distributions may somewhat vary depending on the oscillation design of the laser related to the width of the ridge.

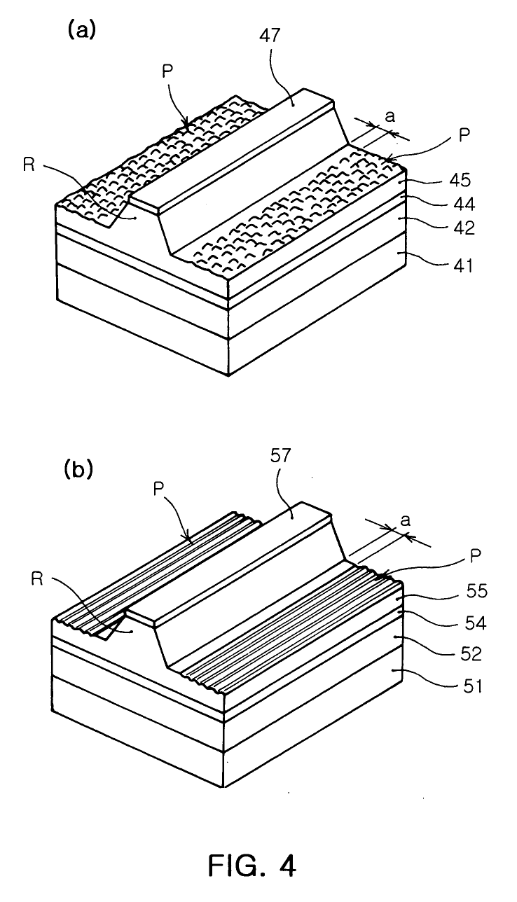

FIGS. 4a and 4b are overall perspective views illustrating semiconductor lasers with diverse form of wave patterns that can be adopted in this invention. The wave patterns P used in the present invention may take diverse forms that can induce light scattering in the main oscillation region of high order mode to result in intentional light loss.

The semiconductor laser device 40 illustrated in FIG. 4a includes a semiconductor substrate 41, and a first conductivity-type cladding layer 42, an active layer 44, and a second conductivity-type cladding layer 45 formed on the semiconductor substrate 41 in their order. The upper area of the second conductivity-type cladding layer 45 has a ridge which may have a second conductivity-type cap layer 47 formed additionally on the top thereof.

The wave patterns P on the upper surfaces of the second conductivity-type cladding layer 45 are positioned in the main oscillation regions of high order mode, which are apart from the ridge R in a predetermined interval a, and are composed of a plurality of irregular waves.

Similar to FIG. 4(a), the semiconductor laser device 50 illustrated in FIG. 4(b) includes a semiconductor substrate 51, and a first conductivity-type cladding layer 52, an active layer 54, a second conductivity-type cladding layer 55, and a second conductivity-type cap layer 57 formed on the semiconductor substrate in their order. The wave patterns P on the upper surfaces of the second conductivity-type cladding layer 55 are positioned in the main oscillation regions of high order mode, which are apart from the ridge in a predetermined interval a, and are composed of waves perpendicular to the ridge R.

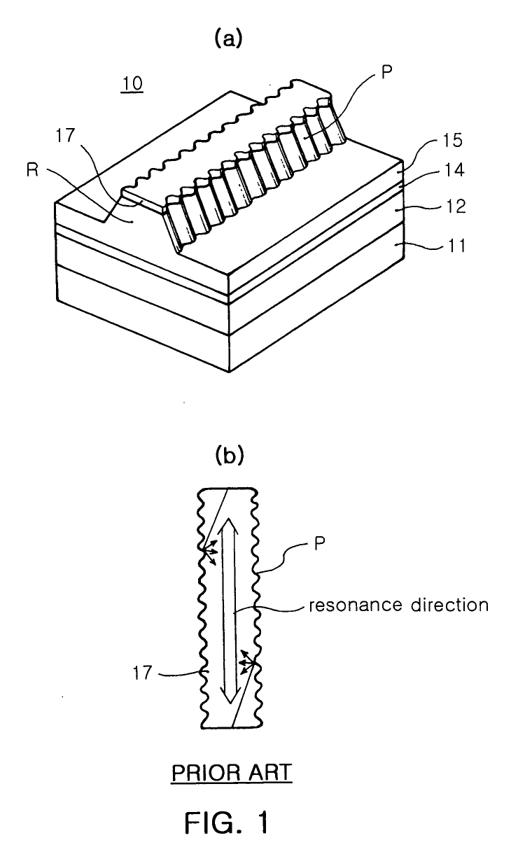

The wave patterns P of the present invention may conveniently be formed via wet-etching process using an appropriate pattern of mask after selective etching process of forming the ridge R. In addition, compared with the conventional structure illustrated in FIG. 1a, the above process allows easier design and manufacturing process of the ridge and obtainment of a ridge with larger width.

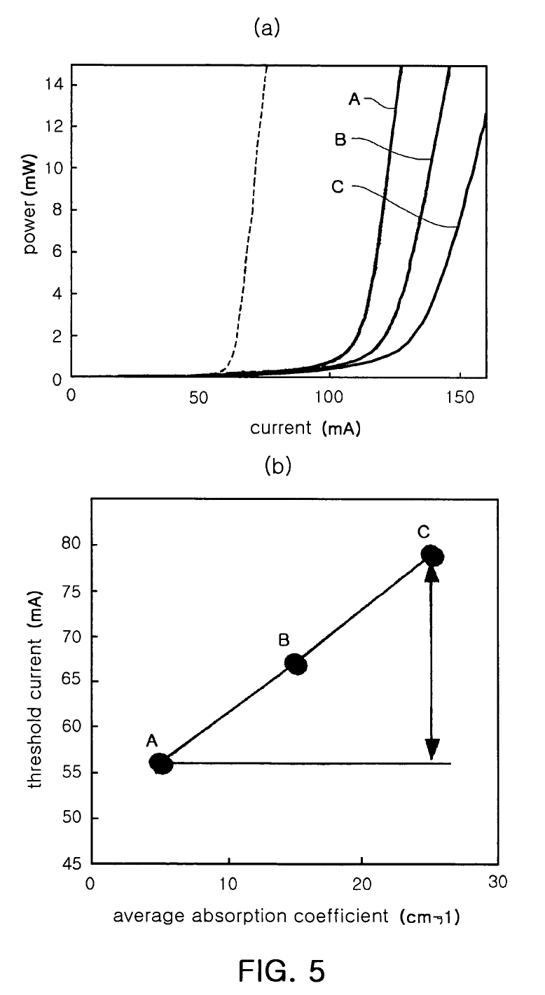

FIG. 5(a) is a graph indicating the relationship between the light of each mode and the current in a semiconductor laser device composed of AlGaInP-based semiconductor layer on an AlGaAs substrate. Here, the dotted line indicates the relationship between the light of the fundamental mode and the current, with the threshold current of oscillation of about 60 mA. In a semiconductor laser (with absorption coefficient of AlGaInP-based material, which is 5 cm⁻¹) without the wave patterns of the present invention, the threshold current of high order mode oscillation is about 110 mA, as designated as A. On the other hand, when the wave patterns are applied on the upper surfaces of the second conductivity-type cladding layer on both sides next to the ridge and thus with the absorption coefficients of 15 cm⁻¹ and 25 cm⁻¹ (designated as B and C), respectively, the threshold currents of high order mode oscillation went up to 123 mA and 135 mA, respectively.

More specifically, as shown in FIG. 5(b), when the absorption coefficient is 25 cm⁻¹ owing to the wave patterns of the present invention, the threshold current is increased by 25 mA from that of the conventional AlGaInP semiconductor laser, which means the increase of kink level by about 70 mW in the actual operation of the semiconductor laser.

As explained above, the increase in the threshold current of high order mode oscillation, and resultant enhancement of the laser characteristics is based on the light loss equivalent to the absorption coefficient induced by the wave patterns formed in the main oscillation region of high order mode.

The preferred embodiment of the present invention has been explained using the example of AlGaInP-based semiconductor laser device, but also with the semiconductor laser devices using other materials such as AlGaAs-based and AlGaInP-based materials, wave patterns for scattering light can be formed on the upper area of the second conductivity-type cladding layer on both sides next to the ridge to induce similar suppression effect of high order mode oscillation.

While the present invention has been shown and described in connection with the preferred embodiments, it will be apparent to those skilled in the art that modifications and variations can be made without departing from the spirit and scope of the invention as defined by the appended claims.

As set forth above, the semiconductor laser device according to the present invention is provided with wave patterns for scattering light formed on the upper area of the second conductivity-type cladding layer on both sides next to the ridge, without changing the structure of ridge, effectively suppressing high order mode oscillation through light loss due to waveguiding scattering in the main oscillation region of high order mode. Therefore, the invention allows convenient designing and forming of the desired ridge structure while maintaining single mode at high power, and also prevents weakening of electrical characteristics due to defective connection with the upper electrode. Furthermore, as the wave patterns are disposed apart from the formation area of electrodes where intensive heat is generated, unstable light scattering effect due to such heat can be minimized.

What is claimed is:

1. A semiconductor laser device comprising:
a semiconductor substrate;
a first conductivity-type cladding layer formed on the semiconductor substrate;
an active layer formed on the first conductivity-type cladding layer; and
a second conductivity-type cladding layer formed on the active layer, the second conductivity-type cladding layer having a ridge protruding upward, and corrugated parts formed on upper surfaces of the second conductivity-type cladding layer on both sides next to the ridge for scattering light in order to suppress high order mode oscillation.

2. The semiconductor laser device according to claim 1, wherein the corrugated parts are formed from lower edges of the ridge.

3. The semiconductor laser device according to claim 1, wherein the corrugated parts are formed apart in a predetermined interval from the lower edges of the ridge.

4. The semiconductor laser device according to claim 1, wherein the corrugated parts comprise wave patterns in parallel to the ridge.

5. The semiconductor laser device according to claim 1, wherein the corrugated parts comprise wave patterns perpendicular to the ridge.

6. The semiconductor laser device according to claim 1, wherein the corrugated parts have irregular spacings and depths.

7. The semiconductor laser device according to claim 1, wherein the corrugated parts have a spacing that is shorter than the wavelength of the laser and longer than ½ of the wavelength of the laser.

8. A fabrication method of a semiconductor laser comprising steps of:
forming a first conductivity-type cladding layer, an active layer, and a second conductivity-type cladding layer in succession on a semiconductor substrate;
selectively etching the upper part of the second conductivity-type cladding layer, thereby forming a ridge protruding upward; and
forming corrugated parts on upper surfaces of the second conductivity-type cladding layer on both sides next to the ridge for scattering light in order to suppress high order oscillation.

9. The fabrication method of the semiconductor laser device according to claim 8, wherein the corrugated parts are formed from the lower edges of the ridge.

10. The fabrication method of the semiconductor laser device according to claim 8, wherein the corrugated parts are formed apart in a predetermined interval from the lower edges of the ridge.

11. The fabrication method of the semiconductor laser device according to claim 8, wherein the corrugated parts comprise wave patterns in parallel to the ridge.

12. The fabrication method of the semiconductor laser device according to claim 8, wherein the corrugated parts comprise wave patterns perpendicular to the ridge.

13. The fabrication method of the semiconductor laser device according to claim 8, wherein the corrugated parts have irregular spacings and depths.

14. The fabrication method of the semiconductor laser device according to claim 8, the corrugated parts have a spacing that is shorter than the wavelength of the laser and longer than ½ of the wavelength of the laser.
